(19) United States
(12) Patent Application Publication
(10) Pub. No.: US 2010/0318865 A1
(43) Pub. Date: Dec. 16, 2010

(54) SIGNAL PROCESSING APPARATUS INCLUDING BUILT-IN SELF TEST DEVICE AND METHOD FOR TESTING THEREBY

(75) Inventors: Jae Wan KIM, Gyeonggi-do (KR); Minsu JEONG, Gyeonggi-do (KR)

Correspondence Address: FOLEY AND LARDNER LLP;SUITE 500, 3000 K STREET NW, WASHINGTON, DC, 20007, US

(73) Assignee: INTEGRANT TECHNOLOGIES INC.

(21) Appl. No.: 12/483,726

(22) Filed: Jun. 12, 2009

(51) Int. Cl. G01R 31/28; G06F 11/00

(52) U.S. Cl. 714/733; 714/E11.001

(57) ABSTRACT

A signal processing apparatus according to the present invention includes: a built-in self test device dividing a digital reference clock signal to output an I division signal and a Q division signal, shifting the I division signal and the Q division signal by predetermined angles, converting the shifted I and Q signal into analog signals to output an I testing signal and a Q testing signal; and a signal processing receiving and processing the I testing signal and the Q testing signal.

### BACKGROUND

1. Field

The present invention relates to a signal processing apparatus including a built-in self test device (BIST) and a testing method thereby.

2. Description of the Related Art

In recent years, a system on chip technology capable of processing wireless signals in one chip has been increasingly important. There are various demands therefore for testing the SoC.

Since a cost for testing the Soc is a great part in total manufacturing costs of the SoC, effort has been achieved to reduce the testing cost of the SoC. To do this, through a BIST included in a chip, the testing cost of the SoC has been reduced.

The BIST reduces testing complexity to lower the testing cost. Upon testing the SoC, the BIST is used to lower dependence on an external testing device in which testing patterns are programmed.

Various researches have been progressed to simply embody the BIST.

### SUMMARY

In one aspect, a signal processing apparatus comprises a built-in self test device dividing a digital reference clock signal to output an I division signal and a Q division signal, shifting the I division signal and the Q division signal by predetermined angles, and converting the shifted I and Q signal into analog signals to output an I testing signal and a Q testing signal and a signal processing receiving and processing the I testing signal and the Q testing signal.

The predetermined angles may be 45° and 90°.

The I testing signal and the Q testing signal may be respectively input to either an I signal processing filter and a Q signal processing filter of the signal processor, or an I signal processing converter and a Q signal processing converter of the signal processor.

The built-in self test device may perform up-conversion or down-conversion of the I testing signal and the Q testing signal to combine the converted I testing signal and Q testing signal, and output the combined signal to either an I signal processing mixer and the Q signal processing mixer or a low noise amplifier.

The built-in self test device may delay the I division signal to output the Q division signal.

The built-in self test device may output a plurality of I division signals with different frequencies.

In another aspect, a signal processing apparatus comprises a divider receiving and dividing a digital reference clock signal to generate an I division signal, a phase delay unit delaying the I division signal to generate a Q division signal, an I signal shifter shifting the I division signal by a predetermined angle, a Q signal shifter shifting the Q division signal by a predetermined angle, a first signal converter scaling the I division signal output from the I signal shifter and the signals shifted by the I signal shifter, and adding the scaled I division signal and the scaled signals, a second signal converter scaling the Q division signal output from the Q signal shifter and the signals shifted by the Q signal shifter, and adding the scaled Q division signal and the scaled signals, I and Q signal filters filtering the signals output from the first and second converter to output an I testing signal and a Q testing signal, respectively and a signal processor receiving and processing the I testing signal and the Q testing signal.

The divider may be a programmable divider.

The divider may output the digital reference clock signal as it is or divide the digital reference clock signal to generate operation clock signals with an oscillation frequency necessary for an operation of the phase delay unit, the I signal shifter, the Q signal shifter, the first signal converter, and the second signal converter.

The phase delay unit may include a D flip-flop.

The phase delay unit may delay the I division signal by 90° to generate the Q division signal.

The I signal shifter and the Q signal shifter may shift the I division signal and the Q division signal by 45° and 90°, respectively.

The signal processing apparatus further comprises a first mixer receiving the I testing signal and a local oscillation signal, and performing up-conversion or down-conversion of a frequency of the I testing signal, a second mixer receiving the Q testing signal and the local oscillation signal, and performing up-conversion or down-conversion of a frequency of the Q testing signal and a combiner combining signals output from the first and second mixers and outputting a combined signal.

A scaling ratio of the I division signal, the signal shifted by 45° from the I division signal, and the signal shifted by 90° from the I division signal may be 1:\sqrt{2}:1, and a scaling ratio of the Q division signal, the signal shifted by 45° from the Q division signal, and the signal shifted by 90° from the Q division signal may be 1:\sqrt{2}:1.

The signal processing apparatus may further comprise a test mode selector outputting the I testing signal and the Q testing signal to either an I signal processing converter and a Q signal processing converter of the signal processor, or an I signal processing filter and a Q signal processing filter of the signal processor.

The signal processing apparatus may further comprise a test mode selector outputting the combined signal from the combiner to either an I signal processing mixer and a Q signal processing mixer of the signal processor, or a low noise amplifier of the signal processor.

The divider may output a plurality of I division signals with different frequencies, and the phase delay unit may shift the plurality of I division signals to output a plurality of Q division signals.

The divider may include a p-th division unit and a (p+1)-th division unit performing n (n is a natural number equal to or greater than 2) division and at least one multiplexer receiving at least one of the digital reference clock signal, or at least one output signal of the p-th division unit or the (p+1)-th division unit to output a selected signal, wherein the (p+1)-th division unit may perform n division of the signal output from the p-th division unit.

The signal processing apparatus may further comprise a division unit dividing the signal output from one of the p-th division unit and the (p+1)-th division unit with a division ratio of m (m is a natural number equal to or greater than 2 other than n).

Each of the I signal shifter and the I signal shifter may include a first shifting group and a second shifting group which are composed of the same number of shifting units, the first shift group may shift the I division signal and the Q division signal by 45°, and the second shift group may shift the I division signal and the Q division signal by 90°.

Each of the I signal shifter and the Q signal shifter may include plural D flip-flops with the same input/output characteristics.

The divider may output the digital reference clock signal as it is or divide the digital reference clock signal to output an operation clock signal, the number of clocks in the operation clock signal supplied during one time period of the I division signal and the Q division signal may be a multiple of eight, and the number of shifting units included in each of the first shifting groups and the second shifting groups may correspond to a share when dividing the clock number of the operation clock signal supplied during the one time period by eight.

In still aspect, a testing method comprises dividing a digital reference clock signal to output an I division signal and a Q division signal, shifting the I division signal and the Q division signal by predetermined angles, respectively, converting the shifted signals into respective analog signals to output an I testing signal and a Q testing signal and receiving and processing the I testing signal and the Q testing signal.

The predetermined angles may be 45° and 90°, respectively.

The I testing signal and the Q testing signal may be filtered and converted into respective digital signals while the I testing signal and the Q testing signal are processed.

The method may further comprise Performing up-conversion or down-conversion of the I testing signal and the Q testing signal to combine them and processing and mixing the combined signals.

The I division signal may be delayed to output the Q division signal.

A plurality of I division signals with different frequencies may be output.

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention. In the drawings:

FIG. 1 is a view illustrating a signal processing apparatus with a BIST in accordance with an embodiment of the present invention;

FIG. 2 is a view illustrating a signal output from the BIST shown in FIG. 1;

FIG. 3 is a view illustrating a signal processing apparatus with a BIST in accordance with another embodiment of the present invention;

FIG. 4 is a view illustrating a divider of the embodiment and another embodiment of the present invention;

FIG. 5 is a view illustrating an I signal shifter or a Q signal shifter of the embodiment and another embodiment of the present invention;

FIG. 6 is a waveform diagram illustrating an operation of an I signal shifter and a Q signal shifter of the embodiment and another embodiment of the present invention; and

FIG. 7 is another waveform diagram illustrating operation of an I signal shifter or a Q signal shifter of the embodiment and another embodiment of the present invention.

### DETAILED DESCRIPTION OF EMBODIMENTS

Reference will now be made in detail embodiments of the invention examples of which are illustrated in the accompanying drawings.

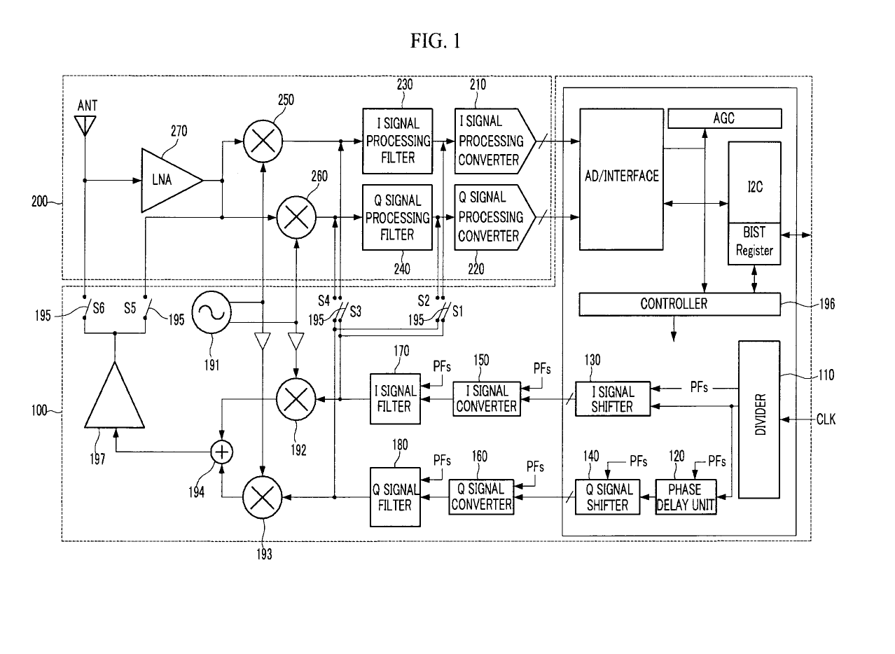

FIG. 1 is a view illustrating a signal processing apparatus with a built-in self test device (BIST) 100 in accordance with an embodiment of the present invention. Referring to FIG. 1, the signal processing apparatus in accordance with the embodiment of the present invention includes a BIST 100 and a signal processor 200.

The BIST 100 generates a testing signal from which harmonic wave components are removed. The signal processor 200 processes the testing signal output from the BIST 100. The processed signal from the signal processor 200 is output to an analysis device (not shown), such that the analysis device checks whether or not the signal processor 200 operates normally.

The BIST 100 includes a divider 110, a phase delay unit 120, an I signal shifter 130, a Q signal shifter 140, a first signal converter 150, a second signal converter 160, an I signal filter 170, a Q signal filter 180, a local oscillator 191, a first mixer 192, a second mixer 193, an adder 194, a test mode selector 195, and a controller 196.

The divider 110 receives and divides a digital reference clock signal CLK to generate an in-phase division signal (referred to as ‘I division signal’ hereinafter). Since the divider 110 divides a digital reference clock signal not an analog signal in the embodiment of the present invention, a construction of the divider 110 is simplified.

In the embodiment of the present invention, the divider 110 may be a programmable divider 110. That is, the programmable divider 110 may receive the digital reference clock signal, and output the I division signal with a predetermined frequency.

When the divider 110 outputs the I division signal with a predetermined frequency, because a signal processing apparatus does not process signals with all bands but processes a signal of a specific frequency, it is unnecessary that the BIST 100 outputs testing signals of all bands. Consequently, the divider 110 outputs the I division signal with the predetermined frequency that allows a construction of the divider 110 to be simplified.

Further, since the divider 110 outputs a division signal with a predetermined frequency, respective constructions of the phase delay unit 120, the I signal shifter 130, the Q signal shifter 140, the first signal converter 150, the second signal converter 160, the I signal filter 170, and the Q signal filter 180 processing the I division signal can be more simplified in comparison with the BIST outputting testing signals of all bands.

Meanwhile, the divider 110 outputs a digital reference clock signal CLK as it is or divides the digital reference clock signal CLK to generate operation clock signals PFs with an oscillation frequency necessary for an operation of the phase delay unit 120, the I signal shifter 130, the Q signal shifter 140, the first signal converter 150, and the second signal converter 160. Accordingly, the operation clock signals PFs of the phase delay unit 120, the I signal shifter 130, the Q signal shifter 140, the first signal converter 150, and the second signal converter 160 may be the same as each other.

The phase delay unit 120 delays the I division signal output from the divider 110 by 90° to generate a quadrature-phase division signal (referred to as ‘Q division signal’ hereinafter). The phase delay unit 120 may include a D flip-flop in order to generate the Q division signal. The D flip-flop receives the I division signal and the operation clock signals PFs from the divider 110, and delays the I division signal by 90° to output a Q division signal. When a number of operation clocks corresponding to 90° are input to the D flip-flop having stored the I division signal, it outputs the stored signal, thereby outputting the Q division signal. As mentioned above, the phase delay unit 120 may simply output the Q division signal through the D flip-flop.

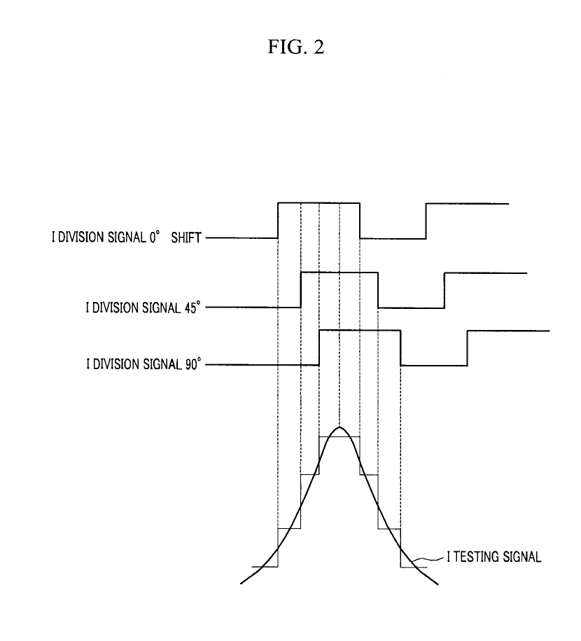

The I signal shifter 130 shifts the I division signal by a predetermined angle. In the embodiment of the present invention, referring to FIG. 2, the I signal shifter 130 shifts the I division signal by 45° and 90°.

Likewise, the Q signal shifter 140 also shifts the Q division signal by a predetermined angle. In the embodiment of the present invention, the Q signal shifter 140 shifts the Q division signal by 45° and 90°.

As noted earlier, the I signal shifter 130 and the Q signal shifter 140 shift the I division signal and the Q division signal, respectively, so as to remove odd-numbered harmonic wave components of the I division signal and the Q division signal being a digital signal.

The I signal shifter 130 and the Q signal shifter 140 may each be a programmable delay unit. Namely, since the I signal shifter 130 and the Q signal shifter 140 delay the I division signal and the Q division signal by a predetermined angle, respectively, constructions of the I signal shifter 130 and the Q signal shifter 140 can be simplified.

The first signal converter 150 scales the I division signal output from the I signal shifter 130 and the signals shifted by the I signal shifter 130, and adds the scaled I division signal and the scaled signals to each other. In this case, a scaling ratio of the I division signal, the signal shifted by 45° from the I division signal, and the signal shifted by 90° from the I division signal is 1:\sqrt{2}:1. Accordingly, a signal shown in a bottom end of FIG. 2 is generated.

The second signal converter 160 also scales the Q division signal output from the Q signal shifter 140 and the signals shifted by the Q signal shifter 140, and adds the scaled Q division signal and the scaled signals to each other. A scaling ratio of the Q division signal, the signal shifted by 45° from the Q division signal, and the signal shifted by 90° from the Q division signal is 1:\sqrt{2}:1.

The I signal filter 170 and the Q signal filter 180 filter the signals output from the first signal converter 150 and the second signal converter 160, to output an i-phase testing signal (referred to as ‘I testing signal’ hereinafter) and a qudrature-phase testing signal (referred to as ‘Q testing signal’ hereinafter), respectively, as shown in FIG. 2. Through operations of the I signal filter 170 and the Q signal filter 180, an I testing signal and a Q testing signal in which harmonic wave components are attenuated, are output.

As mentioned above, the I signal shifter 130 and the Q signal shifter 140 shift and scale the I division signal and the Q division signal by predetermined angles, respectively, and add the scaled signals. Accordingly, the I signal filter 170 and the Q signal filter 180 do not need a complicated circuit arrangement for removing a third harmonic wave and a fifth harmonic wave.

The first mixer 192 receives the I testing signal output from the I signal filter 170 and a local oscillating signal output from the local oscillator 191, and performs up-conversion or down-conversion of the frequency of the I testing signal.

The second mixer 193 receives the Q testing signal output from the Q signal filter 180 and the local oscillating signal output from the local oscillator 191, and performs up-conversion or down-conversion of the frequency of the Q testing signal.

A combiner 194 combines output signals from the first mixer 192 and the second mixer 193, and outputs a combined signal.

In the embodiment of the present invention, although the local oscillator 191 is included in the BIST 100, it may be included in the signal processor 200.

The test mode selector 195 may output the I testing signal from the I signal filter 170 and the Q testing signal from the Q signal filter 180, to either the I signal processing converter 210 and the Q signal processing converter 220 of the signal processor 200 or an I signal processing filter 230 and a Q signal processing filter 240 thereof.

Further, the test mode selector 195 may output the combined signal from the combiner 194 to either an I signal processing mixer 250 and a Q signal processing mixer 260 of the signal processor 200 or a low noise amplifier (LNA) 270 of the signal processor 200. In this case, the LNA 270 may be connected to an antenna (ANT) receiving an external wireless signal.

Through operation of the test mode selector 195, it may be checked whether operation of the signal processor 200 is normally performed.

Namely, when the test mode selector 195 outputs the I testing signal from the I signal filter 170 and the Q testing signal from the Q signal filter 180 to the I signal processing converter 210 and the Q signal processing converter 220 of the signal processor 200, the I signal processing converter 210 and the Q signal processing converter 220 convert the analog I testing signal and the analog Q testing signal into respective digital signals. Next, when it is checked whether or not the digital signals converted from the I signal processing converter 210 and the Q signal processing converter 220 are normal by the analysis device, it is recognized whether operations of the I signal processing converter 210 and the Q signal processing converter 220 of the signal processor 200 are normally performed.

When the test mode selector 195 outputs the I testing signal from the I signal filter 170 and the Q testing signal from the Q signal filter 180 to the I signal processing filter 230 and the Q signal processing filter 240 of the signal processor 200, the I signal processing filter 230 and the Q signal processing filter 240 filter the I testing signal and the Q testing signal, and output the filtered I and Q testing signals to the I signal processing converter 210 and the Q signal processing converter 220, respectively. Next, the I signal processing converter 210 and the Q signal processing converter 220 convert the filtered I and Q testing signals into respective digital signals. Subsequently, when the analysis device checks whether or not the digital signals from the I signal processing converter 210 and the Q signal processing converter 220 are normal, it is recognized that operations of the I signal processing converter 210 and the Q signal processing converter 220 of the signal processor 200 are normally performed.

Moreover, when the test mode selector 195 outputs the combined signal from the combiner 194 to the I signal processing mixer 250 and the Q signal processing mixer 260, the I signal processing mixer 250 and the Q signal processing mixer 260 receive the local oscillating signal from the local oscillator 191, and performs down-conversion or up-conversion of the combined signal. Thereafter, the I signal processing mixer 250 and the Q signal processing mixer 260 output the down-converted or up-converted signals to the I signal processing filter 230 and the Q signal processing filter 240. The filtered I and Q testing signals from the I signal processing filter 230 and the Q signal processing filter 240 are converted into respective digital signals by the I signal processing converter 210 and the Q signal processing converter 220, respectively. Next, when the analysis device checks whether or not the digital signals from the I signal processing converter 210 and the Q signal processing converter 220 are normal, it is recognized that the I signal processing mixer 250, the Q signal processing mixer 260, the I signal processing filter 230, the Q signal processing filter 240, the I signal processing converter 210, and the Q signal processing converter 220 operates normally.

In this case, when the first mixer 192 and the second mixer 193 performs up-conversion of the I testing signal and the Q testing signal, respectively, the I signal processing mixer 250 and the Q signal processing mixer 260 perform down-conversion operations. Furthermore, when the first mixer 192 and the second mixer 193 performs down-conversion of the I testing signal and the Q testing signal, respectively, the I signal processing mixer 250 and the Q signal processing mixer 260 perform up-conversion operations.

When the test mode selector 195 outputs the combined signal from the combiner 194 to the LNA 270 of the signal processor 200, the LNA 270 amplifies and outputs the combined signal to the I signal processing mixer 250 and the Q signal processing mixer 260. Accordingly, through operations of the I signal processing mixer 250, the Q signal processing mixer 260, the I signal processing filter 230, the Q signal processing filter 240, the I signal processing converter 210, and the Q signal processing converter 220, the digital signals are output. Next, when the analysis device checks whether or not the digital signals are normal, it is recognized that the I signal processing mixer 250, the Q signal processing mixer 260, the I signal processing filter 230, the Q signal processing filter 240, the I signal processing converter 210, and the Q signal processing converter 220 are performing normally.

The foregoing test mode selector 195 includes switches S1 to S6 for selecting output paths of the I testing signal and the Q testing signal, and an output path of the combined signal.

First and second switches S1 and S2 allow the I testing signal and the Q testing signal to be output to the I signal processing converter 210 and the Q signal processing converter 220, respectively. Third and fourth switches S3 and S4 allow the I testing signal and the Q testing signal to be output to the I signal processing filter 230 and the Q signal processing filter 240, respectively.

A fifth switch S5 allows the combined signal from the combiner 194 to be output to the I signal processing mixer 250 and the Q signal processing mixer 260. A sixth switch S6 allows the combined signal from the combiner 194 to be output to the LNA 270 of the signal processor 200.

In an embodiment of the present invention, the BIST 100 outputs the I testing signal and the Q testing signal to the signal processor 200 through the test mode selector 195, it may not include the first mixer 192, the second mixer 193, and the adder 194.

As mentioned previously, the BIST 100 divides a digital reference clock signal to output an I division signal and a Q division signal. Then, the BIST 100 shifts the I division signal and the Q division signal by a predetermined angle, and converts and outputs the shifted I and Q division signals into respective analog I and Q testing signals.

That is, in a case of a general BIST such as Direct Digital Frequency Synthesis (DDFS), delta-sigma modulation, or band pass delta-sigma modulation, because analog signals with various frequency bands should be processed, a BIST circuit is complicated, thereby occupying a large area in a chip.

Meanwhile, since the embodiment of the present invention divides a digital reference clock signal to generate a digital I division signal and a digital Q division signal with a predetermined frequency, a BIST circuit is simplified and an occupied area in a chip is reduced.

As described earlier, because the embodiment of the present invention operates using a digital signal, when a digital signal is converted into an analog signal, a third harmonic wave and a fifth harmonic wave are generated. So as to remove the third harmonic wave and the fifth harmonic wave, the embodiment of the present invention shifts the I division signal and the Q division signal by a predetermined angle, and converts the shifted signals into respective analog signals. Through the foregoing procedure, the embodiment of the present invention may provide a BIST of a simple structure capable of removing harmonic waves using a digital signal.

The signal processor 200 receives either the I testing signal and the Q testing signal output from the BIST 100, or a combined signal of the I testing signal and the Q testing signal.

As illustrated previously, it is checked whether or not operation of the signal processor 200 is normal based on a signal output by processing the I testing signal and the Q testing signal by the signal processor 200. Further, it is checked whether or not operation of the signal processor 200 is normal based on a signal output by processing the combined signal by the signal processor 200.

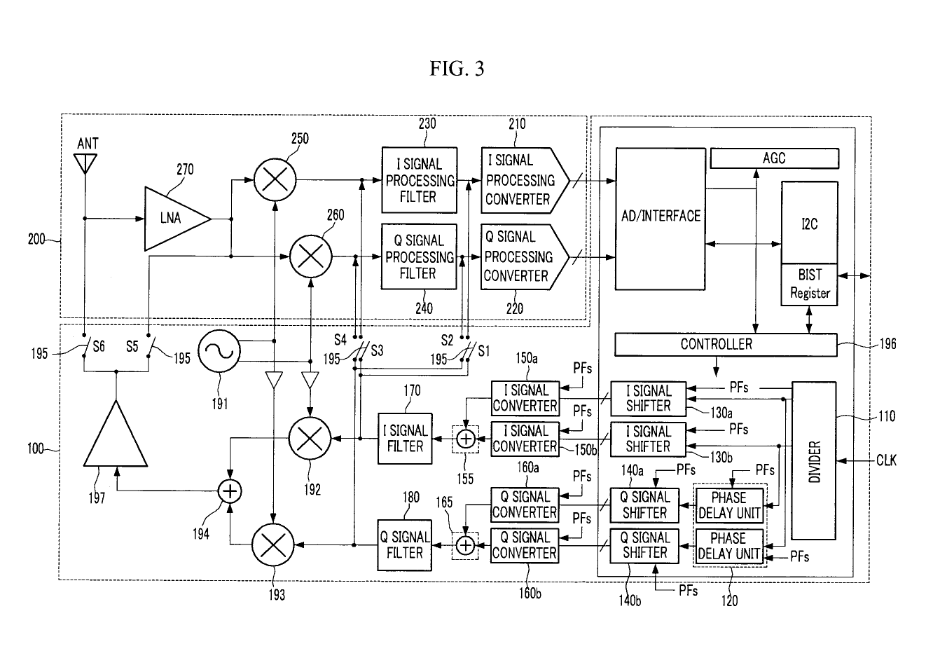

FIG. 3 is a view illustrating a signal processing apparatus with a BIST in accordance with another embodiment of the present invention.

In the BIST of FIG. 1, a divider 110 outputs a single tone. Meanwhile, in the BIST of FIG. 2, a divider 110 may output plural tones, namely, plural in-phase division signals. In this case, the plural in-phase division signals may have different frequencies.

Since the divider 110 outputs plural in-phase division signals, a phase delay unit 120 shifts respective in-phase division signals by 90° to output plural qudrature-phase division signals.

Since the plural in-phase division signals and the plural quadrature-phase division signals are output, a BIST 100 according to another embodiment of the present invention includes plural I signal shifters 130a and 130b, plural Q signal shifters 140a and 140b, first plural signal converters 150a and 150b, second plural signal converters 160a and 160b, an I signal combiner 155, and a Q signal combiner 165. The I signal combiner 155 combines signals output from the first plural signal converters 150a and 150b. The Q signal combiner 165 combines signals output from the second plural signal converters 160a and 160b.

The combined signal from the I signal combiner 155 is input to the I signal filter 170, and the combined signal from the Q signal combiner 165 is input to the Q signal filter 180.

A plurality of tones are required to grasp inter-modulation distortion (IMD) of the signal processor 100. The IMD indicates that an output frequency component is generated by combining the sum and the difference of harmonic frequencies of two input different frequency signals.

That is, the divider 110 of the BIST 100 shown in FIG. 3 divides a digital reference clock CLK to output digital signals with predetermined different frequencies. The digital signals are processed by the I signal shifters 130a and 130b, the Q signal shifters 140a and 140b, the first signal converters 150a and 150b, the second signal converters 160a and 160b, the I signal combiner 155, the Q signal combiner 165, the I signal filter 170, and the Q signal filter 180, thereby outputting the I testing signal and the Q testing signal. The I testing signal and the Q testing signal are input to the signal processor 200 so that the IMD of the signal processor 200 may be grasped.

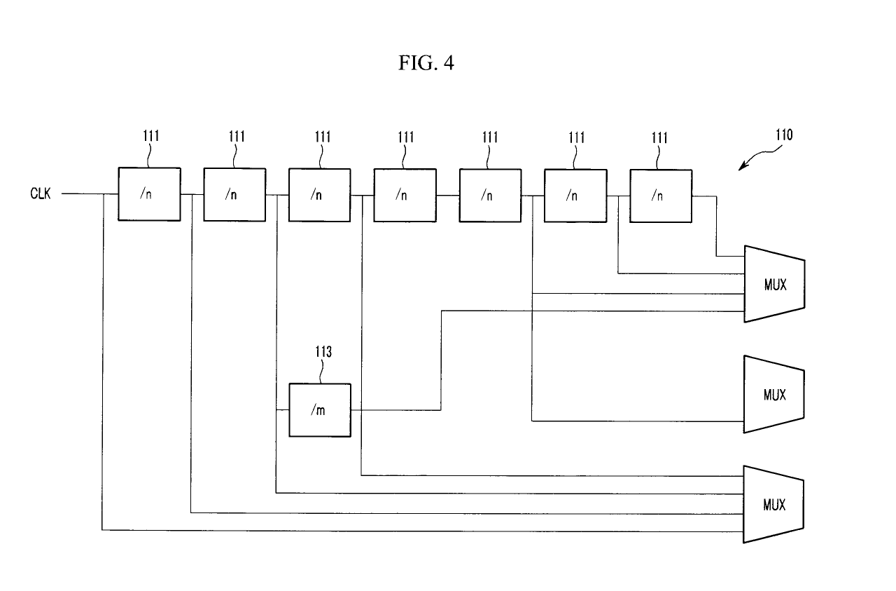

FIG. 4 is a view illustrating a divider according to the embodiment or another embodiment in accordance with another embodiment of the present invention. Referring to FIG. 4, a p (p is a natural number)-th division unit 111, a (p+1)-th division unit 111, and at least one multiplexer MUX. The p-th division unit ill and the (p+1)-th division unit 111 performs n (n is a natural number equal to or greater than 2) division, and the (p+1)-th division unit 111 divides a signal output from the p-th division unit 111 at a division ratio of n.

For example, a first division unit 111 divides a digital reference clock signal CLK with a division ratio of n, and a second division unit 111 divides an output signal of the first division unit 111 with a division ratio of n.

As described above, because the divider 111 of the present invention includes the p-th division unit 111 and the (p+1)-th division unit 111 performing division with a division ratio of n in the same manner, a structure of the divider 11 is simple.

The at least one multiplexer MUX receives at least one of the digital reference clock signal CLK, or at least one of output signals of the p-th division unit 111 or the (p+1)-th division unit 111, and outputs a selected signal.

One of the at least one multiplexer MUX may output an operation clock signal PFs to the phase delay unit 120, the I signal shifter 130, the Q signal shifter 140, the first signal converter 150, and the second signal converter 160. That is, because the operation clock signal PFs is generated by the division unit 111, a structure of the divider 110 is simplified.

The divider 110 according to the present invention may further include a division unit 113 for dividing and outputting the signal output from one of the p-th division unit 111 and the (p+1)-th division unit 111 with a division ratio of m (m is a natural number equal to or greater than 2 other than n) to the multiplexer MUX. Accordingly, signals with various frequencies can be output from the divider 110.

An embodiment of the present invention includes three multiplexers MUX. Two of the three multiplexers MUX may output plural I division signals with different frequencies, and a remaining one thereof may output an operation clock signal PFs. Accordingly, a plurality of tones with different frequencies may be simply generated through the divider 110.

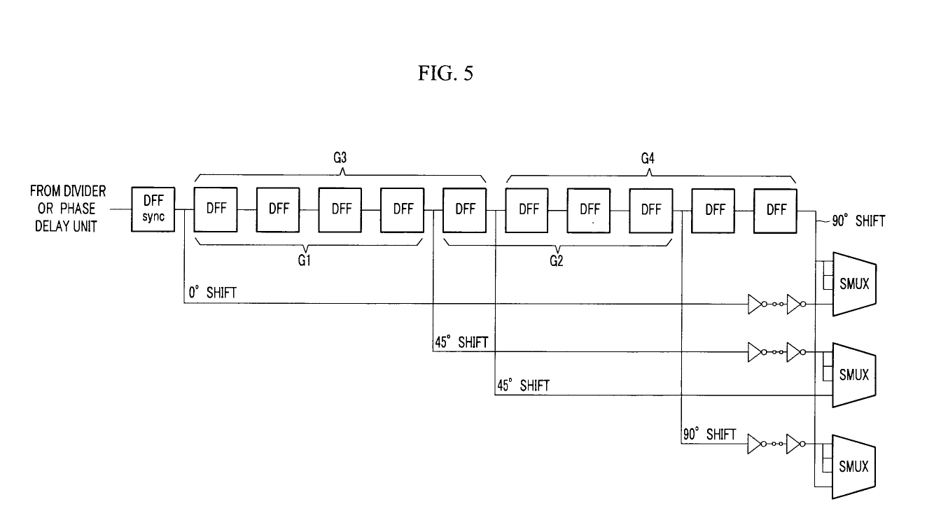

FIG. 5 is a view illustrating an I signal shifter or a Q signal shifter according to an embodiment or another embodiment in accordance with another embodiment of the present invention.

Each of I signal shifter 130, 130a and 130b and Q signal shifter 140, 140a and 140b includes first shifting groups G1, G3, and second shifting groups G2, G4. The first shift group G1 and the second shift group G2 are composed of the same number of shifting units. The first shift group G3 and the second shift group G4 are composed of the same number of shifting units. The first shift groups G1 and G3 shift an I division signal and a Q division signal by 45°, and the second shift groups G2 and G4 shift an I division signal and a Q division signal by 90°.

To perform the operation, each of the I signal shifters 130, 130a and 130b, and the Q signal shifters 140, 140a and 140b include plural D flip-flops with the same input/output characteristics. Since the I signal shifters 130, 130a and 130b, and the Q signal shifters 140, 140a and 140b include the same number of plural D flip-flops, a construction of the I signal shifter or the Q signal shifter is simplified.

A shifting multiplexer SMUX receives and outputs at least one of a signal shifted by 0°, signals shifted by 45° through the first shifting groups G1 and G3, and signals shifted by 90° through the second shifting groups G2 and G4.

A D flip-flop DFFsync arranged in a front stage of the first shifting groups Gl and G3 in FIG. 5 to synchronize a circuit, may be omitted.

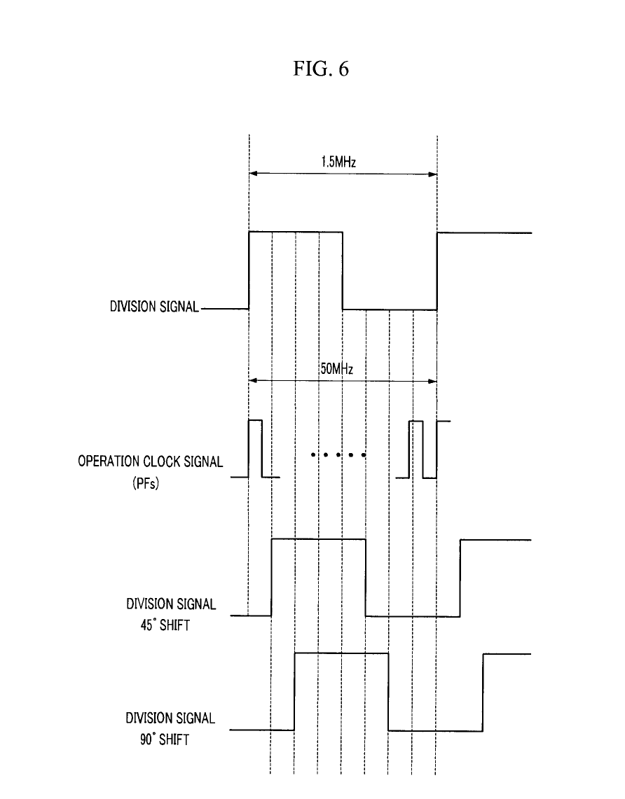

FIG. 6 is a waveform diagram illustrating an operation of an I signal shifter or a Q signal shifter according to an embodiment of the present invention.

Referring to FIG. 6, in a case where the digital reference clock signal CLK has a frequency of 100 MHz, if the divider 110 divides the digital reference clock signal CLK with a division ratio of 64, a division signal has a frequency of approximately 1.5 MHz. Further, when the divider 110 divides the digital reference clock signal CLK with a division ratio of 2, it outputs an operation clock signal PFs of 50 MHz. Accordingly, during one time period of a division signal, the number of clocks of the clock signal PFs is 32(□ 50/1.5).

The division signal and the operation clock signal PFs are input to a signal shifter of FIG. 5. In order to shift a division signal by 45° through the signal shifter, one shifting unit stores the division signal until one clock of an operation clock signal PFs is input. Since 45°(=360°/8) corresponds to 4(=32/8) clocks of the operation clock signal PFs, if one shifting unit stores a division signal until one clock of the operation clock signal PFs is input, the division signal is shifted by 45° through four shifting units and the division signal is shifted by 90° through eight shifting units.

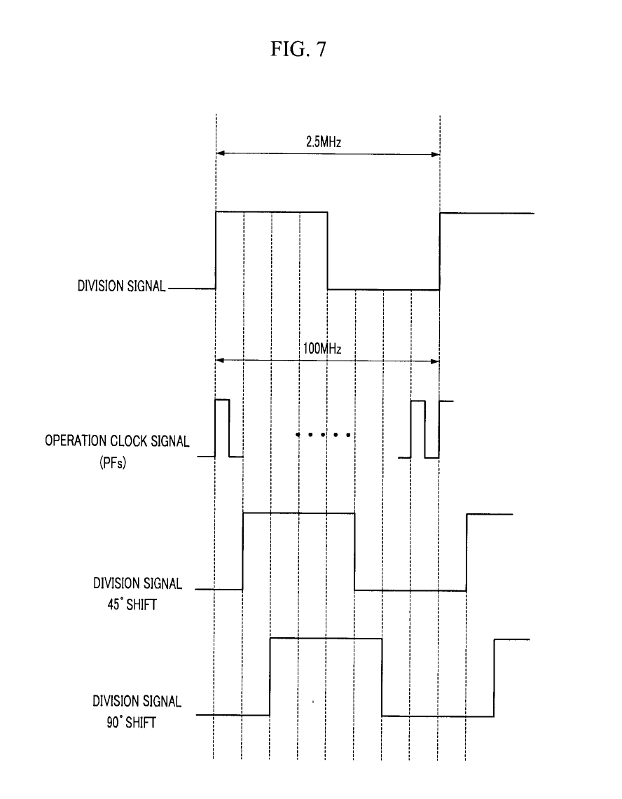

FIG. 7 is another waveform diagram illustrating an operation of an I signal shifter or a Q signal shifter according to an embodiment of the present invention.

In a case where the digital reference clock signal CLK has a frequency of 100 MHz, if the divider 110 divides the digital reference clock signal CLK with a division ratio of 40, a division signal has a frequency of 2.5 MHz. In this case, the divider 110 outputs an operation clock signal PFs of 100 MHz. Consequently, the clock number of the operation clock signal PFs with a high level is 40(=100/2.5) during one period of the division signal.

The division signal and the operation clock signal PFs are input to a signal shifter of FIG. 5. In order to shift a division signal by 45° through the signal shifter, one shifting unit stores the division signal unit one clock of an operation clock signal PFs is input. That is, since 45°(=360°/8) corresponds to 5(=40/8) clocks of the operation clock signal PFs, if one shifting unit stores a division signal until one clock of the operation clock signal PFs is input, the division signal is shifted by 45° through five shifting units and the division signal is shifted by 90° through ten shifting units.

As illustrated with respect to FIG. 5 to FIG. 7, during one time period of the division signal, the clock number of the operation clock signal PFs with a high level supplied is a multiple of 8. The number of shifting units included in each of the first shifting group G1, G3 and the second shifting group G2, G4 corresponds to a share when dividing the clock number of the operation clock signal PFs with a high level supplied during one time period of the division signal by 8.

For example, referring to FIG. 5 and FIG. 6, the number of clocks in an operation clock signal PFs with a high level during one time period of the division signal is 32 being a multiple of 8, and the number of the shifting units included in each of the first shifting group G1 and the second shifting group G2 is 4 (=32/8).

Moreover, as shown in FIG. 5 and FIG. 7, the number of clocks in the operation clock signal PFs with a high level during one time period of the division signal is 40 being a multiple of 8, and the number of the shifting units included in each of the first shifting group and the second shifting group is 5 (=40/8).

In the meantime, in FIG. 1 and FIG. 3, a controller 196 controls the divider 110, the I signal shifters 130a and 130b, the Q signal shifters 140a and 140b, and the test mode selector 195. The controller 196 controls the multiplexer MUX, and the I signal shifters 130a and 130b or the Q signal shifters 140a and 140b of the divider 110, such that the multiplexer MUX selects a specific signal from input signals. In addition, the controller 196 controls switching of the switches S1 to S6 of the test mode selector 195, such that a number of signals generated by the BIST 100 are input to a specific block of the signal processor 200.

For reference, in FIG. 1 and FIG. 3, an A/D interface device is an analog/digital interface for interfacing an I signal processing converter 210 and a Q signal processing converter 220 each outputting an analog signal, and the BIST 110. An AGC of FIG. 1 or FIG. 3 is an automatic gain controller of the BIST 100. An I2C of FIG. 1 or FIG. 3 is a serial computer bus, which is an inter-integrated circuit connected to peripheral devices. Reference numeral 197 of FIG. 1 is an amplifier amplifying a signal output from the combiner.

In an embodiment, a digital signal is used as each of input/output signals of the divider 110, the phase delay unit 120, the I signal shifter 130a and 130b, and the Q signal shifters 140a and 140b. As illustrated previously, digital circuits of the BIST 100 simplify a construction of the BIST 100 but reduce an area of the BIST 100 embodied in a chip.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. A signal processing apparatus comprising:
a built-in self test device dividing a digital reference clock signal to output an I division signal and a Q division signal, shifting the I division signal and the Q division signal by predetermined angles, and converting the shifted I and Q signal into analog signals to output an I testing signal and a Q testing signal; and
a signal processing receiving and processing the I testing signal and the Q testing signal.

2. The signal processing apparatus according to claim 1, wherein the predetermined angles are 45° and 90°.

3. The signal processing apparatus according to claim 1, wherein the I testing signal and the Q testing signal are respectively input to either an I signal processing filter and a Q signal processing filter of the signal processor, or an I signal processing converter and a Q signal processing converter of the signal processor.

4. The signal processing apparatus according to claim 1, wherein the built-in self test device performs up-conversion or down-conversion of the I testing signal and the Q testing signal to combine the converted I testing signal and Q testing signal, and outputs the combined signal to either an I signal processing mixer and the Q signal processing mixer or a low noise amplifier.

5. The signal processing apparatus according to claim 1, wherein the built-in self test device delays the I division signal to output the Q division signal.

6. The signal processing apparatus according to claim 1, wherein the built-in self test device output a plurality of I division signals with different frequencies.

7. A signal processing apparatus comprising:
a divider receiving and dividing a digital reference clock signal to generate an I division signal;
a phase delay unit delaying the I division signal to generate a Q division signal;
an I signal shifter shifting the I division signal by a predetermined angle;
a Q signal shifter shifting the Q division signal by a predetermined angle;
a first signal converter scaling the I division signal output from the I signal shifter and the signals shifted by the I signal shifter, and adding the scaled I division signal and the scaled signals;
a second signal converter scaling the Q division signal output from the Q signal shifter and the signals shifted by the Q signal shifter, and adding the scaled Q division signal and the scaled signals;
I and Q signal filters filtering the signals output from the first and second converter to output an I testing signal and a Q testing signal, respectively; and
a signal processor receiving and processing the I testing signal and the Q testing signal.

8. The signal processing apparatus according to claim 7, wherein the divider is a programmable divider.

9. The signal processing apparatus according to claim 7, wherein the divider outputs the digital reference clock signal as it is or divides the digital reference clock signal to generate operation clock signals with an oscillation frequency necessary for an operation of the phase delay unit, the I signal shifter, the Q signal shifter, the first signal converter, and the second signal converter.

10. The signal processing apparatus according to claim 7, wherein the phase delay unit includes a D flip-flop.

11. The signal processing apparatus according to claim 7, wherein the phase delay unit delays the I division signal by 90° to generate the Q division signal.

12. The signal processing apparatus according to claim 7, wherein the I signal shifter and the Q signal shifter shift the I division signal and the Q division signal by 45° and 90°, respectively.

13. The signal processing apparatus according to claim 7, further comprising:
a first mixer receiving the I testing signal and a local oscillation signal, and performing up-conversion or down-conversion of a frequency of the I testing signal;
a second mixer receiving the Q testing signal and the local oscillation signal, and performing up-conversion or down-conversion of a frequency of the Q testing signal; and
a combiner combining signals output from the first and second mixers and outputting a combined signal.

14. The signal processing apparatus according to claim 12, wherein a scaling ratio of the I division signal, the signal shifted by 45° from the I division signal, and the signal shifted by 90° from the I division signal is 1:\sqrt{2}:1, and a scaling ratio of the Q division signal, the signal shifted by 45° from the Q division signal, and the signal shifted by 90° from the Q division signal is 1:\sqrt{2}:1.

15. The signal processing apparatus according to claim 7, further comprising a test mode selector outputting the I testing signal and the Q testing signal to either an I signal processing converter and a Q signal processing converter of the signal processor, or an I signal processing filter and a Q signal processing filter of the signal processor.

16. The signal processing apparatus according to claim 13, further comprising a test mode selector outputting the combined signal from the combiner to either an I signal processing mixer and a Q signal processing mixer of the signal processor, or a low noise amplifier of the signal processor.

17. The signal processing apparatus according to claim 7, wherein the divider outputs a plurality of I division signals with different frequencies, and the phase delay unit shifts the plurality of I division signals to output a plurality of Q division signals.

18. The signal processing apparatus according to claim 7, wherein the divider includes:
a p-th division unit and a (p+1) -th division unit performing n (n is a natural number equal to or greater than 2) division; and
at least one multiplexer receiving at least one of the digital reference clock signal, or at least one output signal of the p-th division unit or the (p+1)-th division unit to output a selected signal,
wherein the (p+1)-th division unit performs n division of the signal output from the p-th division unit.

19. The signal processing apparatus according to claim 18, wherein further comprising a division unit dividing the signal output from one of the p-th division unit and the (p+1)-th division unit with a division ratio of m (m is a natural number equal to or greater than 2 other than n).

20. The signal processing apparatus according to claim 7, wherein each of the I signal shifter and the I signal shifter includes a first shifting group and a second shifting group which are composed of the same number of shifting units, the first shift group shifts the I division signal and the Q division signal by 45°, and the second shift group shifts the I division signal and the Q division signal by 90°.

21. The signal processing apparatus according to claim 7, wherein each of the I signal shifter and the Q signal shifter includes plural D flip-flops with the same input/output characteristics.

22. The signal processing apparatus according to claim 20, wherein the divider outputs the digital reference clock signal as it is or divides the digital reference clock signal to output an operation clock signal,
the number of clocks in the operation clock signal supplied during one time period of the I division signal and the Q division signal is a multiple of eight, and
the number of shifting units included in each of the first shifting groups and the second shifting groups corresponds to a share when dividing the clock number of the operation clock signal supplied during the one time period by eight.

23. A testing method comprising:
dividing a digital reference clock signal to output an I division signal and a Q division signal;
shifting the I division signal and the Q division signal by predetermined angles, respectively;
converting the shifted signals into respective analog signals to output an I testing signal and a Q testing signal; and
receiving and processing the I testing signal and the Q testing signal.

24. The method according to claim 23, wherein the predetermined angles are 45° and 90°, respectively.

25. The method according to claim 23, wherein the I testing signal and the Q testing signal are filtered and converted into respective digital signals while the I testing signal and the Q testing signal are processed.

26. The method according to claim 23, further comprising:
Performing up-conversion or down-conversion of the I testing signal and the Q testing signal to combine them; and
processing and mixing the combined signals.

27. The method according to claim 23, wherein the I division signal is delayed to output the Q division signal.

28. The method according to claim 23, wherein a plurality of I division signals with different frequencies are output.
